(19) United States
(12) Patent Application Publication
(10) Pub. No.: US 2006/0203114 A1
(43) Pub. Date: Sep. 14, 2006

(54) Three-transistor CMOS active pixel

(75) Inventor: Weize Xu, Rochester, NY (US)

Correspondence Address: Pamela R. Crocker;Patent Legal Staff, Eastman Kodak Company, 343 State Street, Rochester, NY, 14650-2201, US

(73) Assignee: Eastman Kodak Company

(21) Appl. No.: 11/075,431

(22) Filed: Mar. 8, 2005

(51) Int. Cl. H04N 5/335; H04N 3/14; H01L 31/113; H01L 31/062

(52) U.S. Cl. 348/308; 348/302

(57) ABSTRACT

A CMOS image sensor includes a plurality of pixels defining an imaging area each pixel includes a photosensitive area that converts incident light into a charge; a first transistor having a transfer gate that transfers charge from the photosensitive area to a charge-to-voltage region; a second transistor that resets the voltage of the charge-to-voltage region; a third transistor that amplifies voltage from the charge-to-voltage region; and a select mechanism positioned outside the imaging area on the image sensor that selects a predefined number of pixels for readout from the third transistor.

### FIELD OF THE INVENTION

The invention relates generally to the field of CMOS image sensors and, more particularly, to such CMOS image sensors having a three-transistor design with substantially the same sensitivity of a four-transistor design.

### BACKGROUND OF THE INVENTION

With the size of image sensors (the number of pixels) increasing rapidly, smaller pixel size is highly desired. The typical pixels of a CMOS image sensor are either the three- or four-transistor design. The three-transistor design has the desired smaller size but with an undesirable noise level as compared to the four-transistor design. The four-transistor design has higher sensitivity than the three-transistor design, but it obviously occupies a larger spatial area, which is undesirable, and the additional couplings inherent in such a design creates more noise as the pixel size shrinks.

Consequently, a need exists for a pixel of a CMOS transistor to have the sensitivity of the four-transistor design and the size of the three-transistor design.

### SUMMARY OF THE INVENTION

The present invention is directed to overcoming one or more of the problems set forth above. Briefly summarized, according to one aspect of the present invention, the invention resides in a CMOS image sensor comprising a plurality of pixels defining an imaging area each pixel comprising (a) a photosensitive area that converts incident light into a charge; (b) a first transistor having a transfer gate that transfers charge from the photosensitive area to a charge-to-voltage region; (c) a second transistor that resets the voltage of the charge-to-voltage region; (d) a third transistor that amplifies voltage from the charge-to-voltage region; and a select mechanism positioned outside the imaging area on the image sensor that selects a predefined number of pixels for readout from the third transistor.

These and other aspects, objects, features and advantages of the present invention will be more clearly understood and appreciated from a review of the following detailed description of the preferred embodiments and appended claims, and by reference to the accompanying drawings.

Advantageous Effect of the Invention

The present invention has the following advantage of a three-transistor CMOS image sensor with the sensitivity of a four-transistor design.

### BRIEF DESCRIPTION OF THE DRAWINGS

FIG. 1 is a top view of the image sensor of the present invention;

FIG. 2 is a top, detailed view of a typical pixel of FIG. 1; and

FIG. 3 is the typical timing diagram associated for FIG. 2.

### DETAILED DESCRIPTION OF THE INVENTION

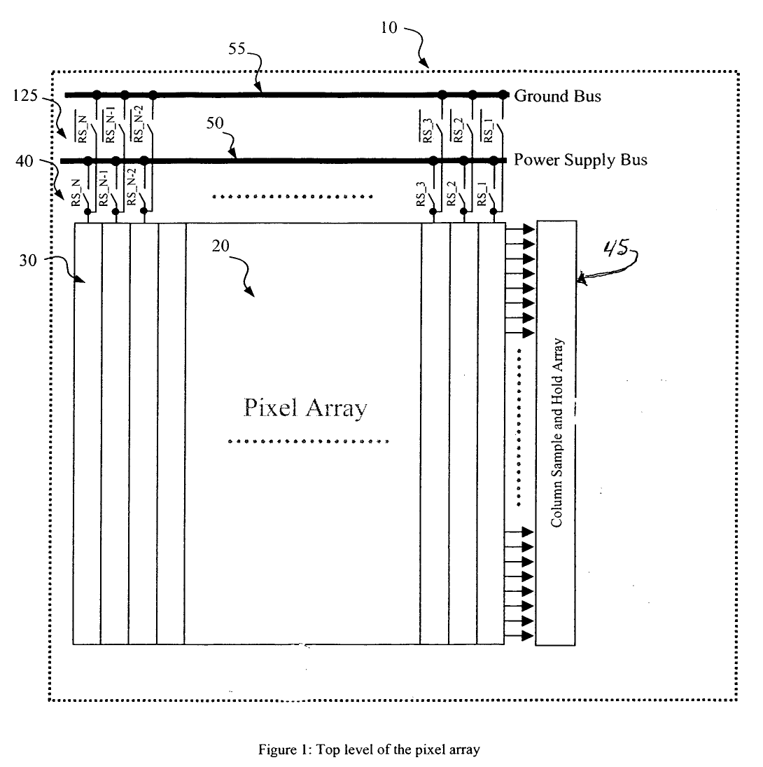

Referring to FIG. 1, there is shown a top view of the CMOS image sensor 10 of the present invention. The image sensor 10 includes an imaging area 20 having a plurality of pixels 30 that defines a boundary for an array of pixels. A plurality of switches 40 is positioned on the CMOS image sensor 10 outside the boundary of the imaging area 20. Each switch 40 is connected to a power supply bus 50 that permits the row of pixels to be selected for readout when the switch 40 is closed as will be discussed in detail hereinbelow. A voltage from each pixel of the row of pixels is then readout to a sample and hold circuit 45, also positioned outside the imaging area 20, for further processing as is well known in the art.

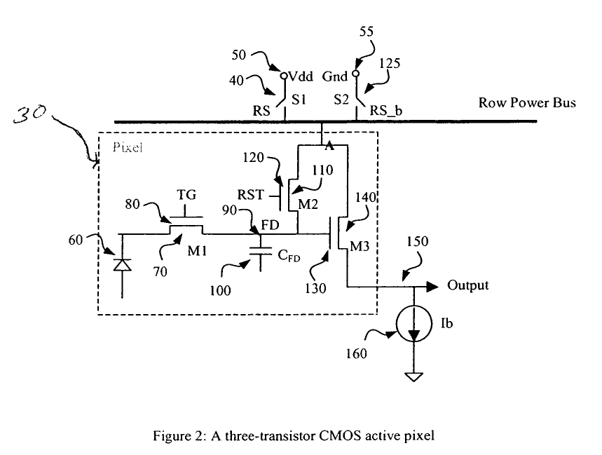

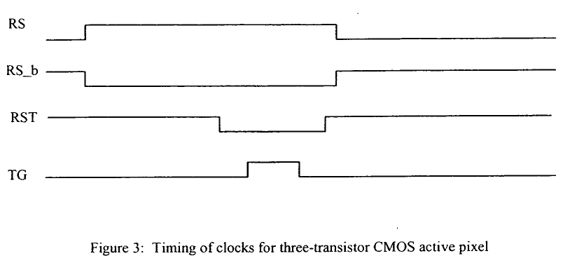

Referring to FIGS. 2 and 3, there are shown a detailed view of a representative pixel 30 of the present invention and its associated timing diagram. Each pixel 30 includes a photodiode or photosensitive area 60 that converts incident light into a charge. A transistor 70 is electrically connected to the photodiode 60 and includes a transfer gate 80 that, when pulsed, permits the charge to pass from the photodiode 60 to a charge-to-voltage conversion region 90, a floating diffusion in the preferred embodiment. A capacitor 100 is electrically connected to the floating diffusion for facilitating the charge-to-voltage conversion by the floating diffusion 90.

A reset transistor 110 is electrically connected to the node of the floating diffusion 90 for resetting the voltage of the floating diffusion 90. In this regard, to reset the voltage of the floating diffusion 90, the row select switch 40 is closed to enable the row of pixels and the reset gate 120 is pulsed for resetting the floating diffusion 90 to the voltage of V_{dd} or substantially close to the voltage of V_{dd}. It is noted that a ground or disable switch 125, which is connected to a ground bus 55, is always in the opposite position as switch 40 for preventing leaking current.

The gate 130 of an amplifying transistor 140 is electrically connected to the floating diffusion 90 for receiving and amplifying the voltage of the floating diffusion 90. The amplifying transistor 140 receives the reset voltage and transfers to the output 150 when the reset transistor 110 is pulsed, as discussed in the preceding paragraph. Then the amplifying transistor 140 receives and transfers the image signal to the output 150 when the transfer gate 80 of the transfer transistor 70 is pulsed, which dumps the charge onto the floating diffusion 90 that consequently is read as a voltage by the amplifying transistor 140, as also discussed above. A bias current 160 is connected to the output of the amplifier for biasing the amplifier.

The output of the amplifier is then readout to a sample and hold circuit array 45 (see FIG. 1).

The invention has been described with reference to a preferred embodiment. However, it will be appreciated that variations and modifications can be effected by a person of ordinary skill in the art without departing from the scope of the invention.

### PARTS LIST

10 image sensor
20 imaging area/pixel array
30 pixels
40 switches
45 sample and hold circuit/circuit array
50 power supply bus
55 ground bus
60 photosensitive area/photodiode
70 transfer gate transistor
80 transfer gate
90 charge-to-voltage conversion region/floating diffusion
100 floating diffusion capacitor
110 reset transistor
120 reset gate
125 ground or disable switch
130 gate of the amplifying transistor
140 amplifying transistor
150 pixel output
160 bias current

1. A CMOS image sensor comprising:
a plurality of pixels defining an imaging area each pixel comprising:
(a) a photosensitive area that converts incident light into a charge;
(b) a first transistor having a transfer gate that transfers charge from the photosensitive area to a charge-to-voltage conversion region;
(c) a second transistor that resets the voltage of the charge-to-voltage conversion region;
(d) a third transistor that amplifies voltage from the charge-to-voltage region; and
(e) a select mechanism positioned outside the imaging area that selects a predefined number of pixels for readout from the third transistor.

2. The CMOS image sensor as in claim 1, wherein the select mechanism is a switch.

3. The CMOS image sensor as in claim 1, wherein the predefined number of pixels is a row of pixels.

4. The CMOS image sensor as in claim 2, wherein the predefined number of pixels is a row of pixels.

5. The CMOS image sensor as in claim 1, wherein the charge-to-voltage conversion region is a floating diffusion.

6. The CMOS image sensor as in claim 5 further comprising a capacitor connected to a node of the floating diffusion.

7. The CMOS image sensor as in claim 3, wherein the select mechanism is a switch.

8. The CMOS image sensor as in claim 1, further comprising a plurality of select mechanisms each operating a predefined number of pixels.

9. The CMOS image sensor as on claim 8, wherein a row of pixels is the predefined number of pixels.

10. The CMOS image sensor as in claim 8, wherein the plurality of select mechanisms are a plurality of switches with each switch operating a predefined number of pixels.

11. The CMOS image sensor as in claim 10, wherein the predefined number of pixels are a row of pixels.
